(19) United States
(12) Patent Application Publication
(10) Pub. No.: US 2023/0358240 A1
(43) Pub. Date: Nov. 9, 2023

(54) Pump Having Monitoring Circuit

(71) Applicant: Brinkmann Pumpen K.H. Brinkmann GmbH & Co. KG, Werdohl (DE)

(72) Inventors: Dirk Wenderott, Castrop-Rauxel (DE); Andreas Vedral, Castrop-Rauxel (DE)

(21) Appl. No.: 18/025,949

(22) PCT Filed: Aug. 25, 2021
(86) PCT No.: PCT/EP2021/073478

§ 371 Date: Mar. 13, 2023

(30) Foreign Application Priority Data
Sep. 16, 2020 (DE) 202020105300.0
Apr. 7, 2021 (DE) 202021101831.3

(51) Int. Cl. F04D 15/00; G01R 15/20; F04B 17/03; F04D 13/06

(52) U.S. Cl. CPC F04D 15/0088; G01R 15/202; F04B 17/03; F04D 13/0693; F04B 2203/0201; F04B 2203/0202; F04B 2201/0801; F04B 2201/0804; F04B 2203/0205

(57) ABSTRACT

A pump having an electric motor (14) and an electronic monitoring circuit (30) arranged in a housing part (26) of the motor, for monitoring and recording operating parameters of the pump, one of the operating parameters being the current consumption of the pump, the monitoring circuit (30) having a digital current and voltage measuring circuit (34) which is integrated in a semiconductor component and has at least one Hall sensor (36) for measuring current.

The invention relates to a pump having an electric motor and an electronic monitoring circuit, arranged in a housing part of the motor, for monitoring and recording operating parameters of the pump, one of the operating parameters being the current consumption of the pump.

Electric pumps are used, in machine tools for example, for supplying a coolant/lubricant liquid to the machining tools and the workpieces where the liquid is collected and, possibly after regeneration or filtering, is recirculated to the suction side of the pump.

Frequently, in a machining shop, a plurality of electric pumps are employed for several tasks, and the pumps have to cooperate with one another and with other equipment in the machining shop in a coordinated manner. Then, a malfunction or a failure of an individual pump may lead to an extended lock down and cause considerable costs. A regular maintenance of the pumps and other components in the machine shop is therefore prerequisite. A close monitoring and maintenance of all components of the equipment also causes considerable costs.

US 2016 076 536 A1 discloses a compressor which has a monitoring circuit for remote monitoring of operating parameters. Among others, the current consumption of the drive motor is monitored.

For measuring the current consumption of AC-powered electric machines, current sensors in the form of Rogowski coils have become known, which surround the current-carrying conductor and in which, due to the magnetic field in the surroundings of the conductor, a voltage is induced that depends upon the intensity of the current. However, such current sensors are relative expensive and, moreover, very bulky, so that it is difficult to accommodate them in or on the motor casing of relatively small-sized pumps such as pumps for coolant/lubricant liquids.

It is an object of the invention to provide a pump that has a compact housing and in which a monitoring circuit is integrated.

According to the invention, this object is achieved by the feature that the monitoring circuit has a digital current and voltage measuring circuit which is integrated in a semiconductor component and has at least one Hall sensor for measuring current.

According to the invention, the current is measured by means of sensors which detect the magnetic field in the surroundings of the conductor by means of the Hall effect. These sensors may be integrated into a semiconductor chip (IC) through which the current to be measured flows through and which also include digital circuitry for evaluating the measurement result. In this way, the costs and in particular the space requirement for the monitoring circuit can be reduced to such an extent that even relatively small pumps can be equipped with an integrated monitoring circuit.

Useful embodiments and further developments of the invention are indicated in the dependent claims.

The operating parameters that are monitored may comprise, in addition to the current consumption of the motor, also the ON time of the pump as well as the operating voltage, so that it is possible for example to adapt the maintenance intervals to the actual operating time of the pump and/or malfunctions may be detected more quickly. Other examples for relevant operating parameters are the speed of revolution of the pump, the temperature at several locations within the motor and the pump and/or accelerations in all three spatial directions, which provide information on possible vibrations or shocks during the operation of the pump.

The operating parameters detected by the monitoring circuit may be stored in a local memory and may then be read in certain intervals, or they may be transmitted in real time to a central unit where they are evaluated and recorded.

For the real time transmission of the data to a central unit, the monitoring circuit may include an interface to a data bus or field bus (e.g. Modbus). There may also be provided connectors for external sensors for measuring for example the pressure and/or the volume flow rate in the outlet port of the pump.

All components of the monitoring circuit may be arranged on a circuit board that can be accommodated in a terminal box that forms part of the motor housing or the motor/pump housing, respectively.

Typically, the terminal box serves for accommodating a so-called terminal board that has six contact pins that may be connected in pairs by means of jumper plugs. The three phases of the current supply cable are connected to three contact pins whereas the three remaining contact pins are connected to the motor windings. Then, a star connection or, alternatively, a delta connection of the motor windings may be realized by rearranging the jumper plugs.

In an embodiment of the invention, the contact pins or else some other contact elements with a different design may be arranged directly on the circuit board so that the circuit board itself may take over the function of the terminal board and an even more compact design becomes possible.

Embodiment examples will now be explained in conjunction with the drawings, wherein:

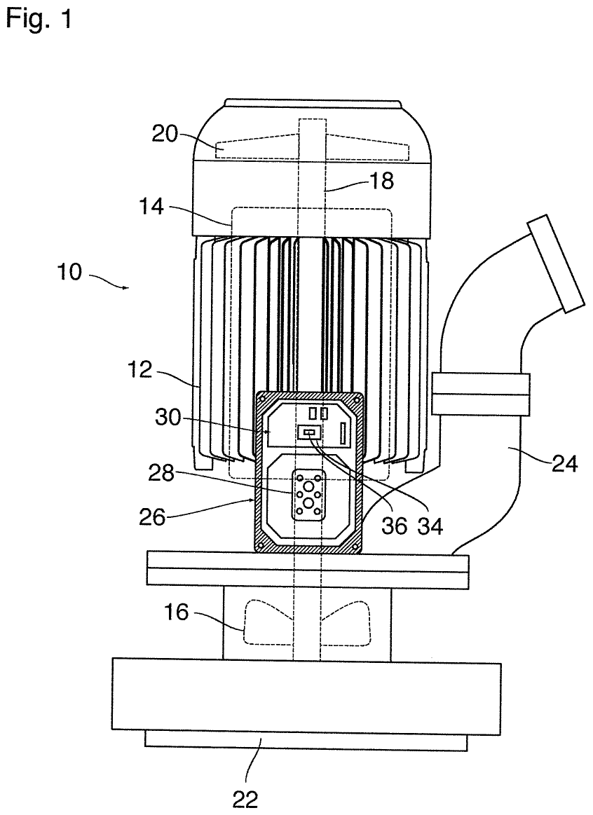

FIG. 1 is a view of an electric pump;

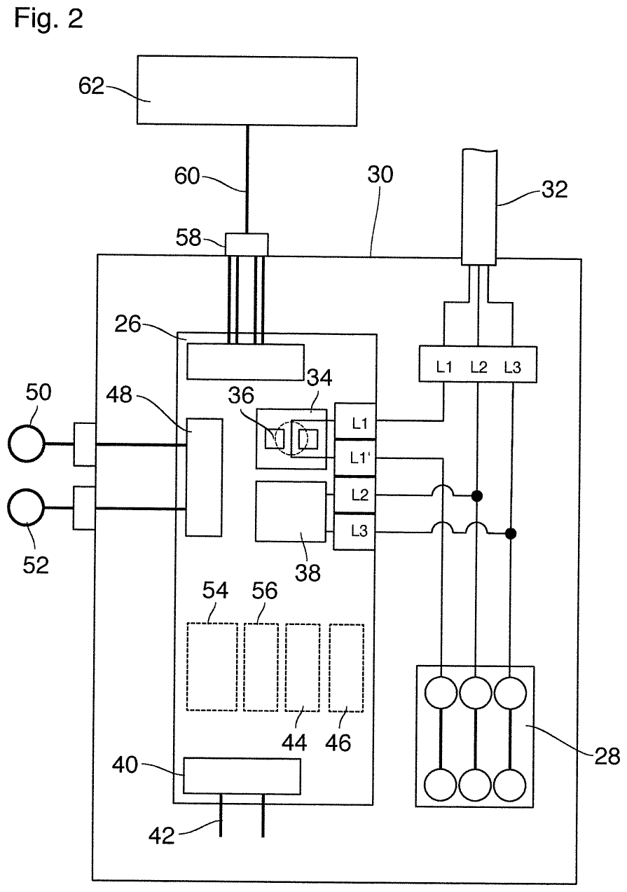

FIG. 2 is a block diagram of an electronic monitoring circuit of the pump; and

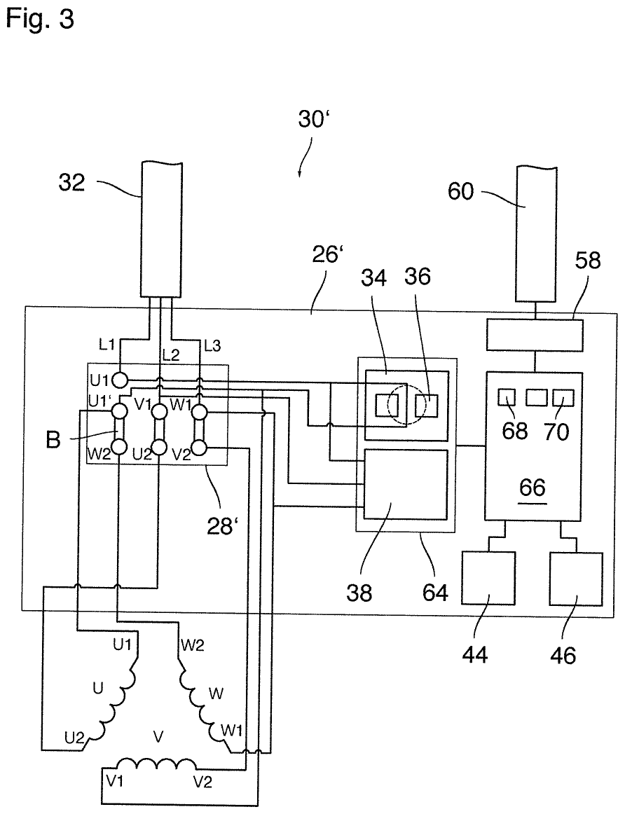

FIG. 3 is a sketch of a monitoring circuit according to another embodiment.

FIG. 1 shows an example of a pump having a housing 10 accommodating an electric motor 14 in a housing section that is formed with cooling fins 12, and, below the same, a pump engine 16. The motor and the pump engine are arranged on a common shaft 18 which carries on its top end a ventilator 20 for cooling the motor.

At its lower end, the housing 10 has a suction port 22 through which a liquid to be pumped, a coolant/lubricant liquid for example, is sucked-in. By means of the pump engine 16, the liquid is displaced into a riser 24 that leads to the machining tools of a machine tool, for example.

At one point of its periphery, on the side facing the viewer in FIG. 1, the housing 10 forms a terminal box 26 that accommodates, as is known in the art, a terminal board 28 for the electric connection of the motor windings. The terminal box 26 has been shown in FIG. 1 with a cover being removed, so that the interior of the terminal box is visible.

Next to the terminal board 28, the terminal box accommodates an electronic monitoring circuit 30, for example in form of circuit board, which is mounted with electronic components and is connected to the connection terminals of the motor and to a monitoring network via lines not shown in the drawing.

In FIG. 2, the monitoring circuit 30 has been shown as a block diagram.

An electric feed line 32 for the motor 14, which enters into the terminal box 26 from outside, has three phases L1, L2, L3. At least one of the three phases (e.g. L1; more preferably two or all three of them) receives a current via a digital current and voltage measuring circuit 34 (power measuring circuit) integrated into or formed by a semiconductor chip (IC) for the purpose of current and voltage measurement and is then connected to the terminal board 28 as terminal L1′. The current and voltage measuring circuit 34 has a plurality of Hall sensors 36 for measuring the current intensity on the basis of the induced magnetic filed. The current intensity that has been measured in this way is processed digitally in the IC in order to determine all relevant performance parameters (active power, apparent power, reactive power).

The phases L2 and L3 are directly connected to the terminal board 28. For measuring the voltages of the phases L2 and L3, a connection from the terminal board 28 to a voltage measuring circuit 38 is provided for each of these phases.

Via an interface 40, the monitoring circuit receives signals 42 from several temperature sensors that detect the temperature at several critical points in the motor and/or the pump. For example, the internal temperature of the terminal box 26 and the temperature of the motor windings may be measured.

Moreover, the monitoring circuit 30 includes an acceleration sensor 44 for measuring any possible accelerations (vibrations) of the pump housing in all three directions of space, as well as an acoustic sensor 46 for monitoring the running noise of the pump.

Via another interface 48, various sensors 50, 52, such as pressure, volume flow rate, or level sensors for measuring relevant process parameters (exit pressure, displacement volume, fill level) may be connected to the monitoring circuit via electric leads. The interface 48 includes analogue/digital converters by which the analogue signals transmitted by the sensors are digitized.

The measured data (operating parameters) captured by the monitoring circuit 30, i.e. the measured voltages, currents, temperatures and accelerations, the volume flow rate and the pressure, may be stored inside the monitoring circuit 30 in a non-volatile memory 54 together with related time stamps and may be read-out from time to time via an RIFD interface 56.

Further, the monitoring circuit 30 is configured for performing a certain pre-evaluation of the captured data, so that any possible anomalies that require an intermediate intervention of the maintenance personnel can be detected without delay. For example, an excessively high leakage or also a jam of the pump engine, as the case may be, (as may be caused for example by chippings contained in the coolant/lubricant liquid) may be detected by comparing the current consumption to the detected output pressure or volume flow rate.

A bus interface 58 and a data bus 60 (field bus) connect the monitoring circuit 30 to a monitoring network or to a central unit 62 which may optionally also evaluate monitoring data from other pumps and other equipment. As soon as the monitoring circuit 30 detects an anomaly, an alarm message can immediately be transmitted to the central unit 62 via the data bus 60. Optionally, the data captured by the various sensors may also be reported in real time to the central unit 62 and be evaluated there.

FIG. 3 shows a monitoring circuit 30′ according to another embodiment. The essential difference in comparison to the monitoring circuit 30 that has been described before is that the components of the monitoring circuit are mounted on a circuit board 26′ that at the same time has the function of a terminal board 28′.

The three phases L1, L2 and L3 of the electric feed line 32 are clamped to three contacts U1, V1 and W1 located on a region of the circuit board 26′ that has the function of a terminal board 28′. The contact U1 is connected to another contact U1′ via the current and voltage measuring circuit 34. The three contacts U1, V1 and W1 as well as three further contacts W2, U2 and V2 are arranged at equal distances in two parallel rows as in a conventional terminal board and may be connected in different configurations by means of jumper plugs B. Further, three motor windings U, V, W of the motor 14 have been shown schematically in FIG. 3, these windings being connected between the contacts of the terminal board 28′ in delta connection in the example shown. For clarity, the opposite ends of each motor winding have been designated with the reference signs of the contacts to which they are connected. Optionally, a star connection of the motor windings could be realized by rearranging the jumper plugs B.

Although the voltage at the contact Ul could also be measured with the current and voltage measuring circuit 34 in order to detect also the phase difference between the current and the voltage, the voltage measuring circuit 38 is in this example configured for measuring the voltages of all three phases. Consequently, it is electrically connected to each of the contacts U1, V1 and W1 . Together, the current and voltage measuring circuit 34 and the voltage measuring circuit 38 form a power measuring circuit 64 the measurement results of which are transmitted to a microprocessor 66 for further evaluation in this example. The microprocessor 66 evaluates also the measurement results of the acceleration sensor 44 and the acoustic sensor 46 and optionally also the signals of other sensors which have not been shown here as they had already been described in conjunction with FIG. 2.

The bus interface 58 accesses data in memory regions 68, 70 of different size in the microprocessor where the data to be transmitted to the central unit 62 (FIG. 2) are buffered. For example, the memory region 68 may store the most relevant monitoring results in the form of relative short bit sequences which can then be transmitted to the central unit 62 with a high clock rate, i.e. essentially in real time. In contrast, in order to avoid an overload of the bus 60, more detailed monitoring results, which have a larger data volume, may be stored in the memory region 70 and may be transmitted in larger intervals or on demand only, e.g. only when the contents of the memory region 68, that are transmitted in real time, hint to the occurrence of a malfunction.

What is claimed is:

1. A pump comprising:
an electric motor and
an electronic monitoring circuit arranged in a housing part of the motor, for monitoring and recording operating parameters of the pump, one of the operating parameters being current consumption of the pump, the monitoring circuit including a digital current and voltage measuring circuit which is integrated in a semiconductor component and has at least one Hall sensor for measuring current.

2. The pump according to claim 1, wherein the housing part that accommodates the monitoring circuit is a terminal box of the pump.

3. The pump according to claim 1, wherein the monitoring circuit is configured for measuring at least one of the following operating parameters in addition to the current consumption of the motor:
operating voltage of the motor;
temperature in the housing part;
temperature at at least one location in the motor or the pump;
volume flow rate of the pump;
output pressure of the pump;
mechanical acceleration of the pump housing part; and
running noise of the pump as captured by an acoustic sensor.

4. The pump according to claim 1, wherein the monitoring circuit is configured for storing at least some of the monitored parameters as a function of time.

5. The pump according to claim 4, wherein the monitoring circuit includes an RIFD interface for reading memory contents.

6. The pump according to claim 1, wherein the monitoring circuit has a bus interface for transmitting data to one of:
an external monitoring network or
a central monitoring unit.

7. The pump according to claim 1, wherein components of the monitoring circuit and contacts of a terminal board are arranged on a common circuit board.
